(19) United States
(12) Patent Application Publication
(10) Pub. No.: US 2025/0096132 A1
(43) Pub. Date: Mar. 20, 2025

(54) METAL TIP-TO-TIP SCALING

(71) Applicant: International Business Machines Corporation, Armonk, NY (US)

(72) Inventors: Ruilong Xie, Niskayuna, NY (US); Brent A. Anderson, Jericho, VT (US); Nicholas Anthony Lanzillo, Wynantskill, NY (US); Lawrence A. Clevenger, Saratoga Springs, NY (US); Reinaldo Vega, Mahopac, NY (US); Albert M. Chu, Nashua, NH (US)

(21) Appl. No.: 18/469,618

(22) Filed: Sep. 19, 2023

(51) Int. Cl. H01L 23/528; H01L 21/768; H01L 23/522

(52) U.S. Cl. CPC H01L 23/5283; H01L 21/7682; H01L 21/76838; H01L 23/5226

(57) ABSTRACT

Embodiments provide metal tip-to-tip scaling for metal contacts. A structure includes a first metal line and a second metal line. The structure includes a spacer separating the first metal line from the second metal line, the spacer including a flat surface and curved tips, where the flat surface abuts the first metal line and the curved tips abut the second metal line.

### BACKGROUND

The present invention generally relates to fabrication methods and resulting structures for integrated circuits (ICs), and more specifically, to fabrication methods and resulting structures for providing metal tip-to-tip scaling for metal contacts.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

The BEOL is the second portion of IC fabrication where a network of vias and lines (known collectively as interconnect structures) of the IC is formed. The IC's individual devices, such as transistors, capacitors, resistors, etc., are formed in earlier layers of the IC and communicatively coupled with one another using the interconnect structures in the BEOL layers of the wafer. The BEOL layer that includes the interconnection of wiring is referred to as the metallization layer, which generally begins when the first layer of metal is deposited on the wafer. BEOL layers of the IC generally include contacts, insulating layers (dielectrics), metal levels, bonding sites for chip-to-package connections, etc.

As the devices on the ICs become smaller, smaller spacing is needed between metal contacts.

### SUMMARY

Embodiments of the present invention are directed to providing metal tip-to-tip scaling for metal contacts. A non-limiting method includes forming a first metal line and a second metal line. The method includes forming a spacer separating the first metal line from the second metal line, the spacer including a flat surface and curved tips, where the flat surface abuts the first metal line and the curved tips abut the second metal line.

According to one or more embodiments, a non-limiting method includes forming a spacer separating a first metal line and a second metal line and removing the spacer so as to leave a cavity between the first metal line and the second metal line. The method includes depositing dielectric material to form an airgap spacer in the cavity between the first metal line and the second metal line and to form a dielectric cap above the first and second metal lines.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and a cross-sectional view of a portion of an integrated circuit (IC) under-fabrication after fabrication operations according to one or more embodiments of the invention;

FIGS. 2A and 2B respectively depict a top view and a cross-sectional view of a portion of an IC under-fabrication after fabrication operations according to one or more embodiments of the invention;

FIGS. 3A and 3B respectively depict a top view and a cross-sectional view of a portion of an IC under-fabrication after fabrication operations according to one or more embodiments of the invention;

FIGS. 4A and 4B respectively depict a top view and a cross-sectional view of a portion of an IC under-fabrication after fabrication operations according to one or more embodiments of the invention;

FIGS. 5A and 5B respectively depict a top view and a cross-sectional view of a portion of an IC under-fabrication after fabrication operations according to one or more embodiments of the invention;

FIGS. 6A and 6B respectively depict a top view and a cross-sectional view of a portion of an IC under-fabrication after fabrication operations according to one or more embodiments of the invention;

FIGS. 7A and 7B respectively depict a top view and a cross-sectional view of a portion of an IC under-fabrication after fabrication operations according to one or more embodiments of the invention;

FIGS. 8A and 8B respectively depict a top view and a cross-sectional view of a portion of an IC under-fabrication after fabrication operations according to one or more embodiments of the invention;

FIGS. 9A and 9B respectively depict a top view and a cross-sectional view of a portion of an IC under-fabrication after fabrication operations according to one or more embodiments of the invention;

FIGS. 10A and 10B respectively depict a top view and a cross-sectional view of a portion of an IC under-fabrication after fabrication operations according to one or more embodiments of the invention;

FIGS. 11A and 11B respectively depict a top view and a cross-sectional view of a portion of an IC under-fabrication after fabrication operations according to one or more embodiments of the invention;

FIGS. 12A and 12B respectively depict a top view and a cross-sectional view of a portion of an IC under-fabrication after fabrication operations according to one or more embodiments of the invention;

FIGS. 13A and 13B respectively depict a top view and cross-sectional view of a portion of an IC under-fabrication after fabrication operations according to one or more embodiments of the invention;

FIGS. 14A and 14B respectively depict a top view and a cross-sectional view of a portion of an IC under-fabrication after fabrication operations according to one or more embodiments of the invention;

FIGS. 15A and 15B respectively depict a top view and a cross-sectional view of a portion of an IC under-fabrication after fabrication operations according to one or more embodiments of the invention;

FIG. 16 depicts a cross-sectional view of a portion of an IC under-fabrication after fabrication operations according to one or more embodiments of the invention;

FIG. 17 depicts a cross-sectional view of a portion of an IC under-fabrication after fabrication operations according to one or more embodiments of the invention;

FIG. 18 depicts a cross-sectional view of a portion of an IC under-fabrication after fabrication operations according to one or more embodiments of the invention;

FIG. 19 depicts a cross-sectional view of a portion of an IC under-fabrication after fabrication operations according to one or more embodiments of the invention;

FIG. 20 depicts a cross-sectional view of a portion of an IC under-fabrication after fabrication operations according to one or more embodiments of the invention;

FIG. 21 depicts a cross-sectional view of a portion of an IC under-fabrication after fabrication operations according to one or more embodiments of the invention; and

FIG. 22 depicts a cross-sectional view highlighting angles in a portion of an IC under-fabrication after fabrication operations according to one or more embodiments of the invention.

### DETAILED DESCRIPTION

Embodiments of the present invention are directed to providing metal tip-to-tip scaling for metal contacts. According to one or more embodiments, a non-limiting structure includes a first metal line and a second metal line, and a spacer separating the first metal line from the second metal line, the spacer having a flat surface and curved tips, where the flat surface abuts the first metal line and the curved tips abut the second metal line.

Technical effects and technical advantages provide improved metal tip-to-tip scaling between metal lines as device sizes decrease. Technical effects and advantages provide metal line tip-to-tip space scaling by using (only) a self-aligned dielectric spacer. As further technical effects and advantages, the removal of one side of the self-aligned spacer followed by additional metal fill results in the self-aligned spacer with improved metal tip-to-tip distance.

In addition to one or more of the features described above or below, additional features include where the second metal line includes a metal extension, the metal extension being separated from the first metal line by the spacer. As technical effects and technical advantages, the metal tip-to-tip spacing is reduced by adding the metal extension to the second metal line.

In addition to one or more of the features described above or below, additional features include where the second metal line includes a metal extension, the metal extension having a larger dimension in one direction than the second metal line. As technical effects and technical advantages, the metal tip-to-tip spacing is reduced by adding the metal extension to the second metal line, and the larger dimension in the z-axis is available for contact to other metal lines or conductive vias.

In addition to one or more of the features described above or below, additional features include where the second metal line includes a metal extension, the metal extension having a larger dimension in one direction than the first metal line. As technical effects and technical advantages, the metal tip-to-tip spacing is reduced by adding the metal extension to the second metal line, and the larger dimension in the z-axis is available for contact to other metal lines or conductive vias.

In addition to one or more of the features described above or below, additional features include where a top surface of the spacer is coplanar with the first metal line and the second metal line. As technical effects and technical advantages, the top surfaces of the first and second metal lines are available for subsequent fabrication operations, while providing the scaled metal tip-to-tip separation.

In addition to one or more of the features described above or below, additional features include where the flat surface and the curved tips are on opposite sides of the spacer. As technical effects and technical advantages, the spacer is an insulator with a unique structure that physically and electrically separates the first and second metal lines.

In addition to one or more of the features described above or below, additional features include where the spacer has an airgap. As technical effects and technical advantages, the airgap reduces any capacitance between the first and second metal lines.

According to one or more embodiments, a non-limiting method includes forming a first metal line and a second metal line, and forming a spacer separating the first metal line from the second metal line, the spacer having a flat surface and curved tips, where the flat surface abuts the first metal line and the curved tips abut the second metal line.

Technical effects and technical advantages provide improved metal tip-to-tip scaling between metal lines as device sizes decrease. Technical effects and advantages provide metal line tip-to-tip space scaling by using (only) a self-aligned dielectric spacer. As further technical effects and advantages, the removal of one side of the self-aligned spacer followed by additional metal fill results in the self-aligned spacer with improved metal tip-to-tip distance.

According to one or more embodiments, a non-limiting method includes forming a spacer separating a first metal line and a second metal line, and removing the spacer so as to leave a cavity between the first metal line and the second metal line. The method includes depositing dielectric material to form an airgap spacer in the cavity between the first metal line and the second metal line and to form a dielectric cap above the first and second metal lines.

Technical effects and technical advantages provide improved metal tip-to-tip scaling between metal lines as device sizes decrease. Technical effects and advantages provide metal line tip-to-tip space scaling by using (only) a self-aligned dielectric spacer. As further technical effects and advantages, the removal of one side of the self-aligned spacer followed by additional metal fill results in the self-aligned spacer with improved metal tip-to-tip distance. Technical effects and advantages include the removal of the solid spacer and the formation of the airgap spacer that reduces any capacitance between the first and second metal lines.

In addition to one or more of the features described above or below, additional features include where the airgap spacer includes an airgap. Technical effects and advantages include the reduction of any capacitance by having the airgap between the first and second metal lines.

In addition to one or more of the features described above or below, additional features include where the airgap spacer includes a flat surface and curved tips, the flat surface abutting the first metal line and the curved tips abutting the second metal line. Technical effects and advantages include the airgap spacer with surfaces for separating the first and second metal lines.

In addition to one or more of the features described above or below, additional features include where the second metal line includes a metal extension, the metal extension being separated from the first metal line by the airgap spacer. Technical effects and advantages include the metal extension for providing a surface for further fabrication operations.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

ICs are typically formed from a large number of semiconductor devices and conductive interconnect layers. More specifically, during the first portion of chip-making (i.e., the front end of line (FEOL) stage), the individual components (transistors, capacitors, etc.) are fabricated on the wafer. The middle of line (MOL) stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically is not enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks of the circuit. Thus, global interconnects are typically thick, long, and more widely separated local interconnects. Vertical connections between interconnect levels (or layers), called metal-filled vias, allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

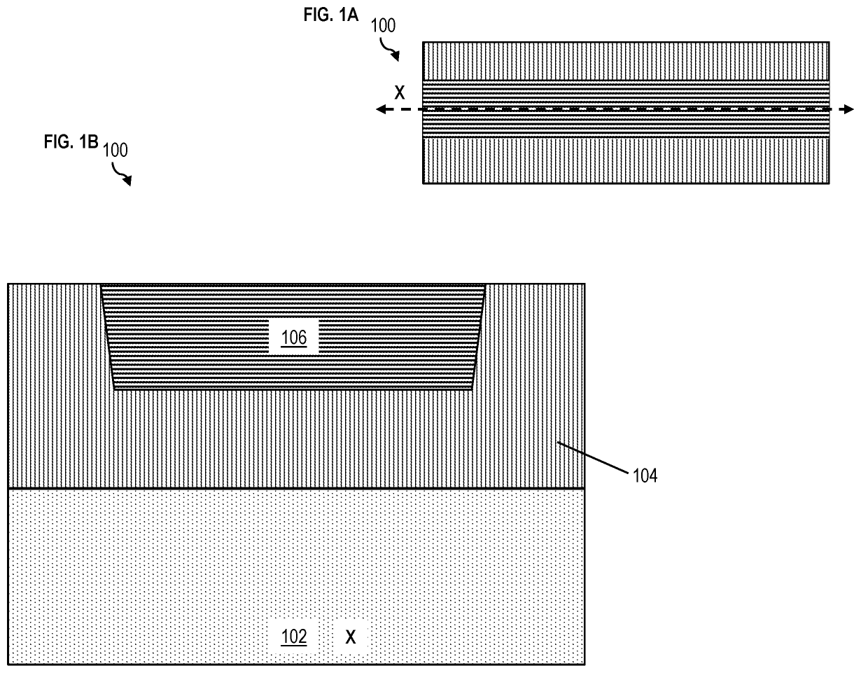

Turning now to a more detailed description of aspects of the present invention, FIG. 1A depicts a top view of a simplified illustration of a portion of an integrated circuit (IC) 100 and FIG. 1B depicts a cross-sectional view taken along X of the IC 100. For ease of understanding, some layers may be omitted from the various top views so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

FIGS. 1A and 1B depict the IC 100 having a wafer where several fabrication processes have been performed. FIGS. 1A and 1B illustrate the IC 100 after fabrication operations. The IC 100 can be part of the BEOL, and there can be many other devices already fabricated in an underlayer 102. Metal formation (or certain placeholder material) is performed to form a metal layer 106, which can be referred to as M1 or Mx. The metal layer 106 is formed in an interlayer dielectric (ILD) layer 104. The material of the metal layer 106 can be Ru, copper, aluminum, tungsten, Co, gold, etc. A thin adhesion metal liner such as TiN and/or TaN is usually deposited too before the metal fill. The ILD material of the ILD layer 104 can be chosen such that later formed materials have etch selectivity. The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

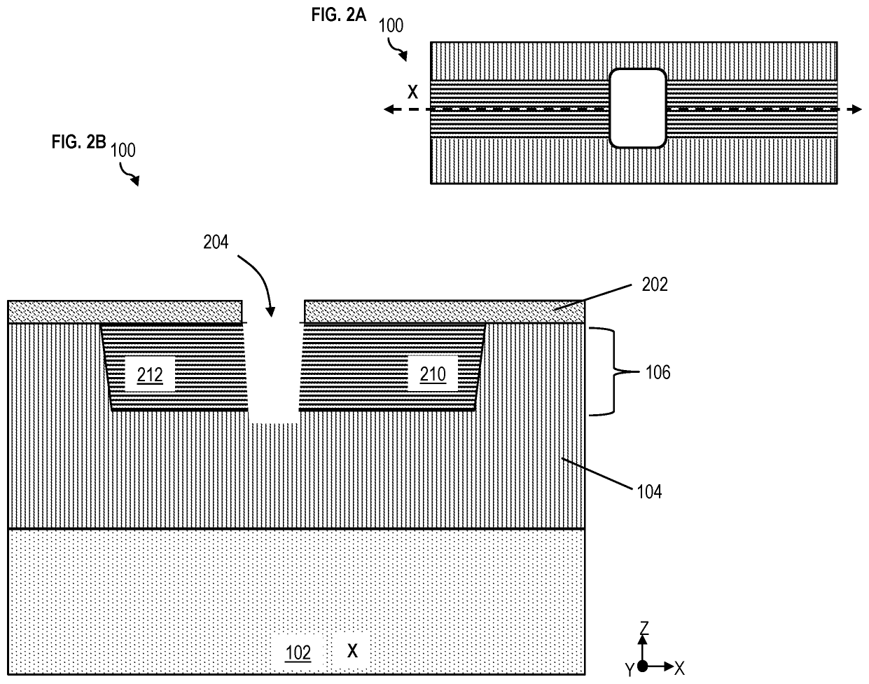

FIGS. 2A and 2B depict the IC 100 after a metal layer cut. A hard mask layer 202 is formed on top of the metal layer 106 and the ILD layer 104. The hard mask layer 202 is patterned, and the patterned hard mask layer 202 is utilized to etch through the metal layer 106 into the ILD layer 104, forming cavity 204. The etching of the metal layer 106 results in two metal lines, illustrated as metal line 210 and metal line 212, which are physically separated by the cavity 204. A dry etch may be utilized. Example materials of the hard mask layer 202 can include nitride materials such as silicon nitride, TiN, SiON, etc.

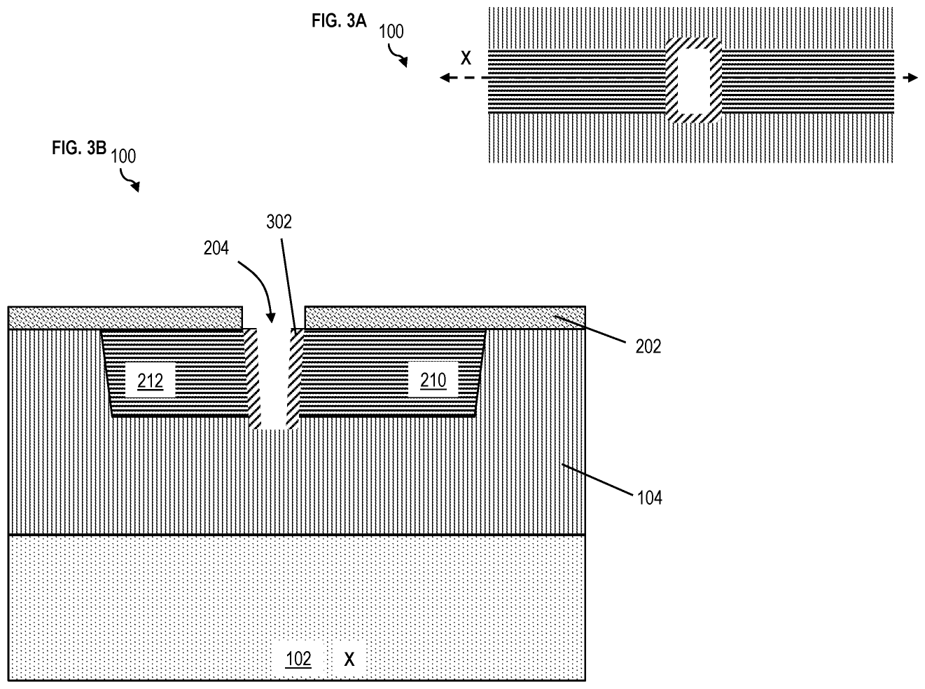

FIGS. 3A and 3B depict the IC 100 after the first insulator spacer formation. A dielectric material is deposited followed by anisotropic etch process to form a spacer 302, which may be referred to as the first spacer. The spacer 302 is a self-aligned spacer. The spacer 302 can include silicon dioxide, SiN, SiC, SiOC, AlOx, AlNx, etc.

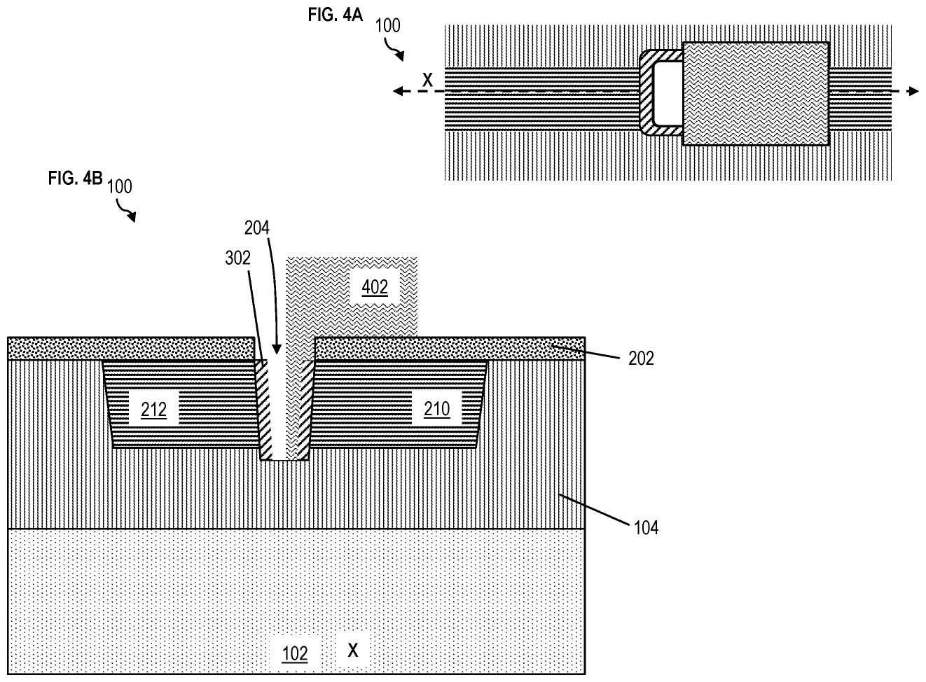

FIGS. 4A and 4B depict the IC 100 after spacer protection patterning. Protective material can be deposited and patterned to form mask 402 that protects a portion of the spacer 302 from subsequent fabrication operations. The other portion of the spacer 302 is exposed. The material of the mask 402 may include anti-reflective coating (ARC) layer, organic planarization layer (OPL) and/or other suitable materials.

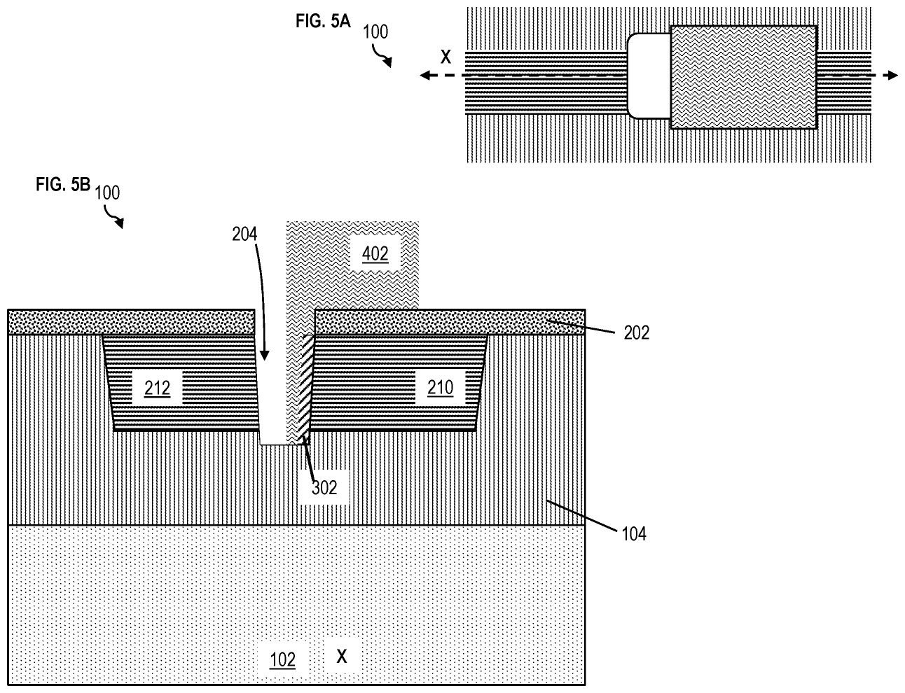

FIGS. 5A and 5B depict the IC 100 after removing the exposed spacer. The unprotected spacer material is removed, while the protected portion of the spacer 302 remains protected.

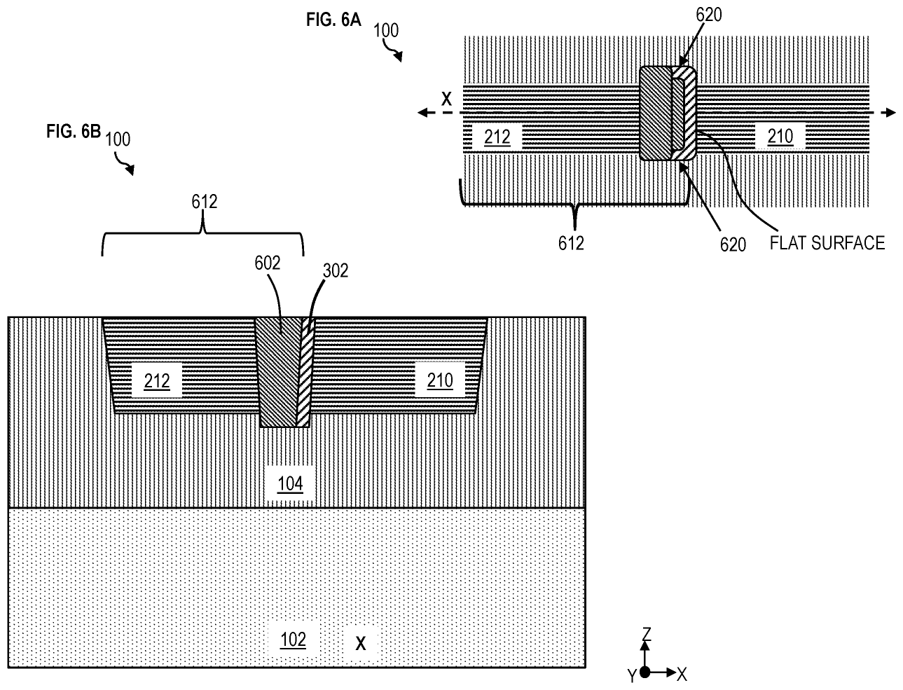

FIGS. 6A and 6B depict the IC 100 after depositing additional metal to extend the length of one of the metal lines. The mask 402 is removed. For example, OPL material can be removed by ashing. Additional metal material is deposited to form a metal extension 602 of the metal line 212. The combination of the metal extension 602 and the metal line 212 form an aggregated metal line 612. Material of the metal extension 602 can include Ru, copper, aluminum, Co, W, gold, etc.

The IC 100 includes an interconnect structure, where the spacer 302 isolates the two ends (e.g., from tip-to-tip) of the metal line 210 and metal line 212. The spacer 302 has a flat surface that abuts the metal line 210, and as hook-like tips or curved tips 620 that abut the metal extension 602 of the aggregated metal line 612. The metal extension 602 is connected to the metal line 212, such that the aggregated metal line 612 is isolated from the metal line 210 by the spacer 302. The metal extension 602 has a larger dimension in the z-axis than the metal line 210 or the metal line 212. Particularly, a bottom surface of the metal extension 602 extends below the bottom surfaces of the metal line 210 and metal lines 212, while the top surfaces of the metal extension 602, the metal lines 210, and the metal line 212 are coplanar.

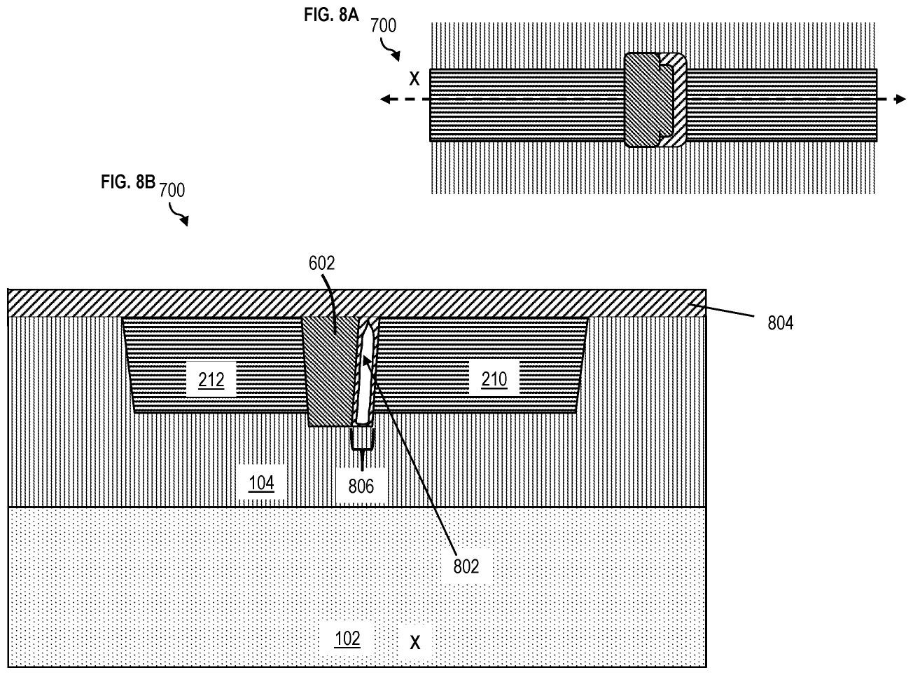

The thickness of the spacer 302, as well as the airgap spacer 806 depicted in FIGS. 8A and 8B, is smaller than a thickness that could have been achieved using lithography to form the spacer. In one or more embodiments, the thickness of the spacer 302 (as well as the airgap spacer 806) could be about 6 nanometers (nm). In one or more embodiments, the thickness of the spacer 302 (as well as the airgap spacer 806) can range from about 4-7 nm. Accordingly, the spacer 302 (as well as the airgap spacer 806) can provide a tip-to-tip spacing between the metal lines 210 and the metal lines 212 of about 4-7 nm.

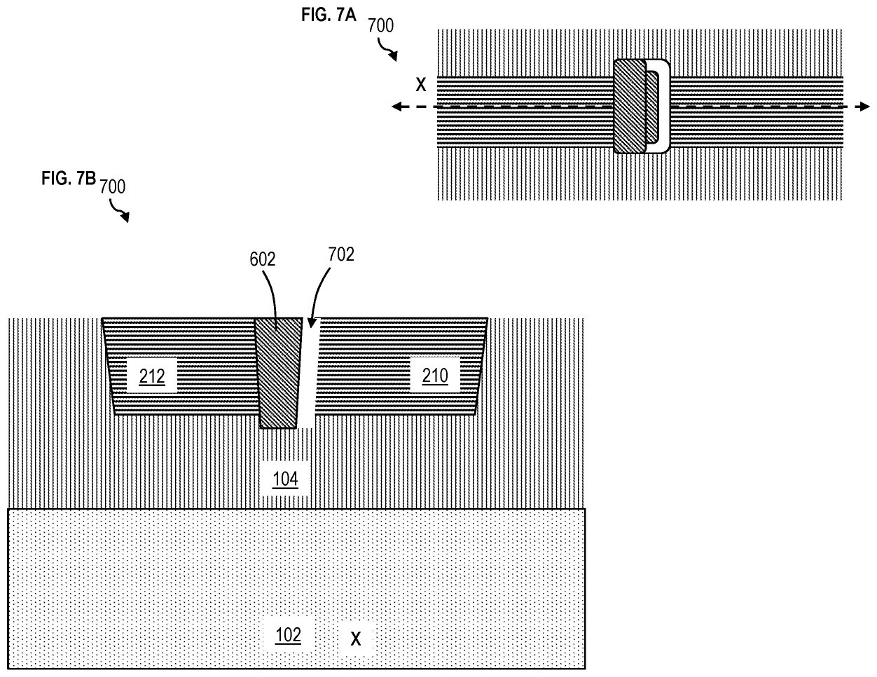

According to one or more embodiments, modification to the interconnect structure of the IC is shown in FIGS. 7A, 7B, 8A, and 8B. FIGS. 7A, 7B, 8A, and 8B depict an airgap spacer utilized to separate the metal line 210 and the metal line 212, according to one or more embodiments. Continuing from fabrication operations of the IC 100 shown in FIGS. 1A-6B, FIGS. 7A and 7B depict the IC 700 after selectively removing the insulator spacer. Etching is performed to selectively remove the spacer 302 leaving a cavity 702. In one or more embodiments, the spacer 302 could formed of silicon germanium such that the silicon germanium material can be selectively removed, while the ILD layer 104 and the metal of the metal line 210, the metal line 212, and the metal extension 602 remain.

FIGS. 8A and 8B depict the IC 700 after forming a dielectric cap and airgap spacer. Dielectric material is deposited as a second insulator. The dielectric material forms a dielectric cap 804 and is deposited in the cavity 702 so as to form an airgap spacer 806 having an airgap 802. The dielectric material can be deposited by atomic layer deposition (ALD) so as to cause the airgap spacer 806 to be formed with the airgap spacer 806.

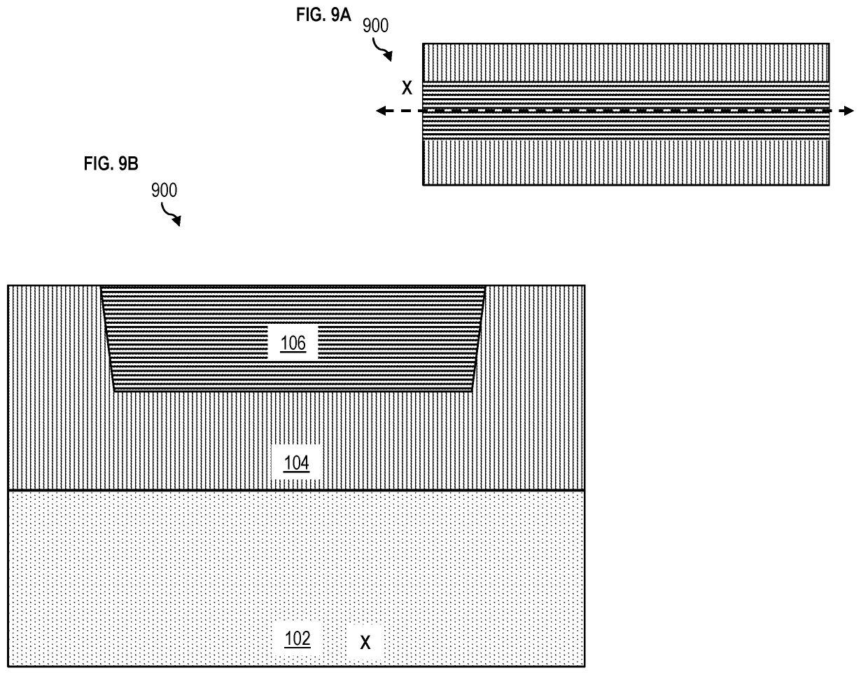

According to one or more embodiments, FIGS. 9A-22 depict fabrication operations for an IC 900. FIGS. 9A and 9B depict the IC 900 having a wafer where several fabrication processes have been performed, analogous to FIGS. 1A and 1B. FIG. 9A depicts a top view of a simplified illustration of a portion of the IC 900 and FIG. 9B depicts a cross-sectional view taken along X of the IC 900. For ease of understanding, some layers may be omitted from the various top views so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein. In FIGS. 9A and 9B, the metal layer 106 is formed in the ILD layer 104.

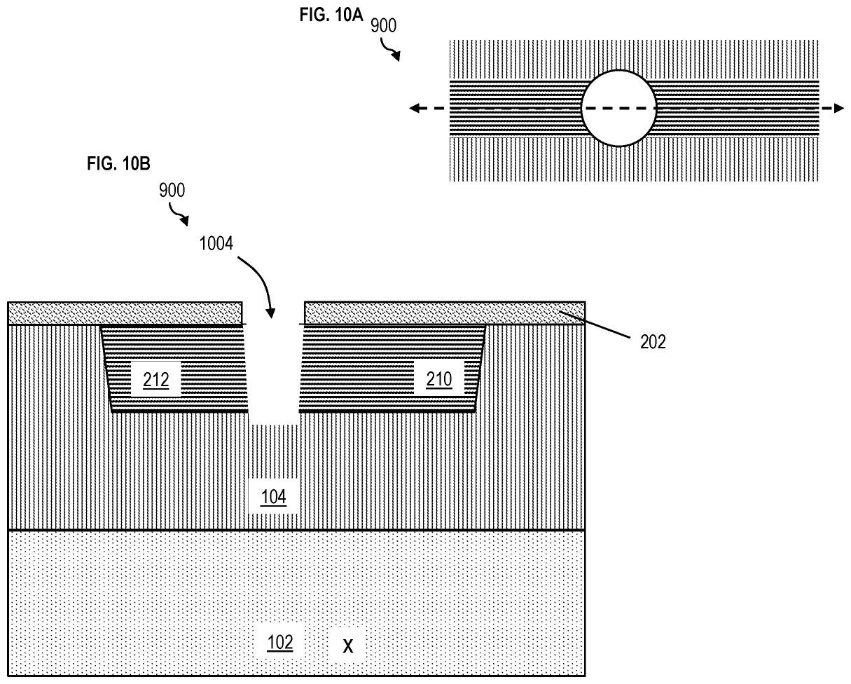

FIGS. 10A and 10B depict the IC 900 after a metal layer cut. The hard mask layer 202 is patterned, and the patterned hard mask layer 202 is utilized to etch through the metal layer 106 into the ILD layer 104, forming cavity 1004. The etching of the metal layer 106 results in two metal lines, illustrated as metal line 210 and metal line 212, which are physically separated by the cavity 1004. A wet etch or dry etch may be utilized. Example materials of the hard mask layer 202 can include nitride materials such as silicon nitride.

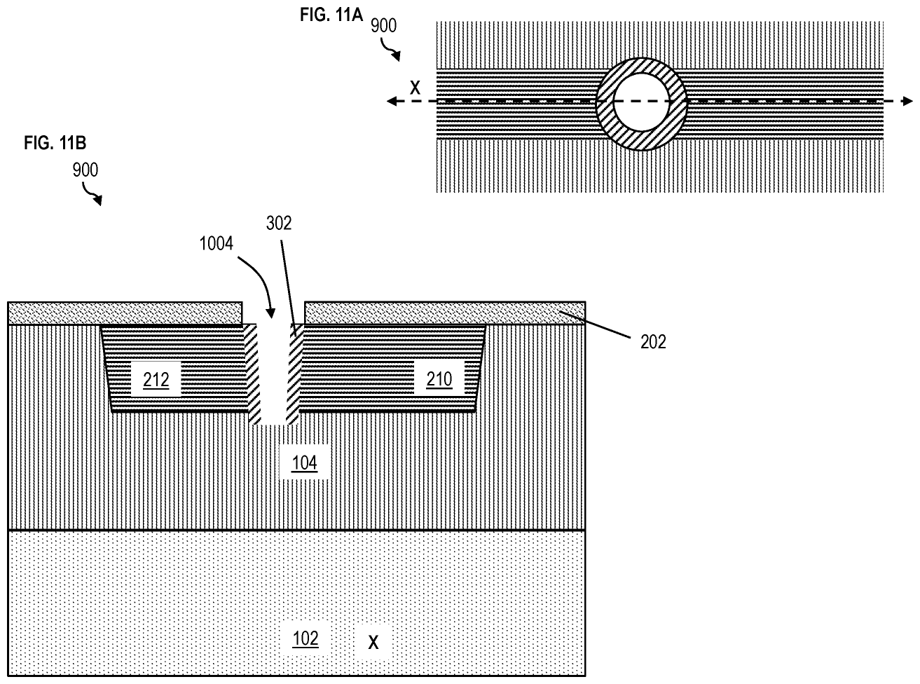

FIGS. 11A and 11B depict the IC 900 after the first insulator spacer formation. A dielectric material is deposited to form the spacer 302, which may be referred to as the first spacer. The spacer 302 can include silicon dioxide, SiN, SiOC, SiC, SiBCN, SiOCN, AlOx, AlNx, etc.

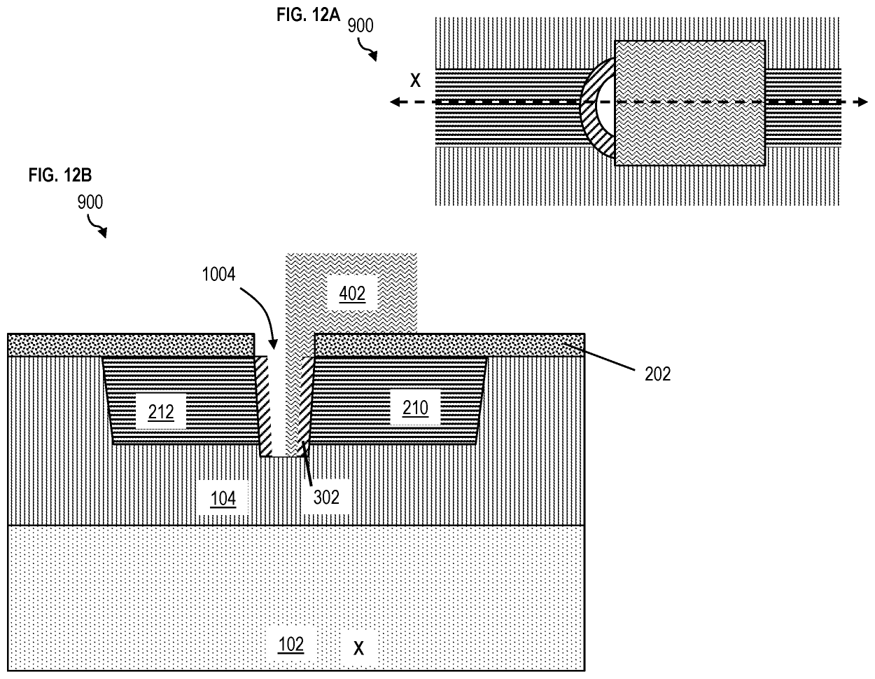

FIGS. 12A and 12B depict the IC 900 after spacer protection patterning. Protective material can be deposited and patterned to form mask 402 that protects a portion of the spacer 302 from subsequent fabrication operations. The other portion of the spacer 302 is exposed. The material of the mask 402 may include an ARC layer, an organic planarization layer (OPL) and/or other suitable materials.

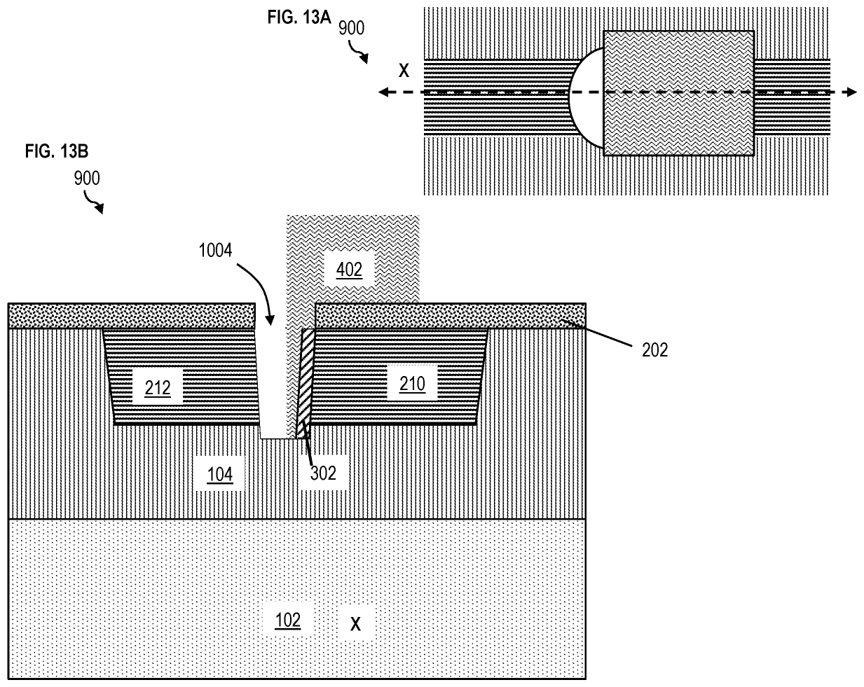

FIGS. 13A and 13B depict the IC 900 after removing the exposed spacer. The unprotected spacer material is removed, while the protected portion of the spacer 302 remains protected.

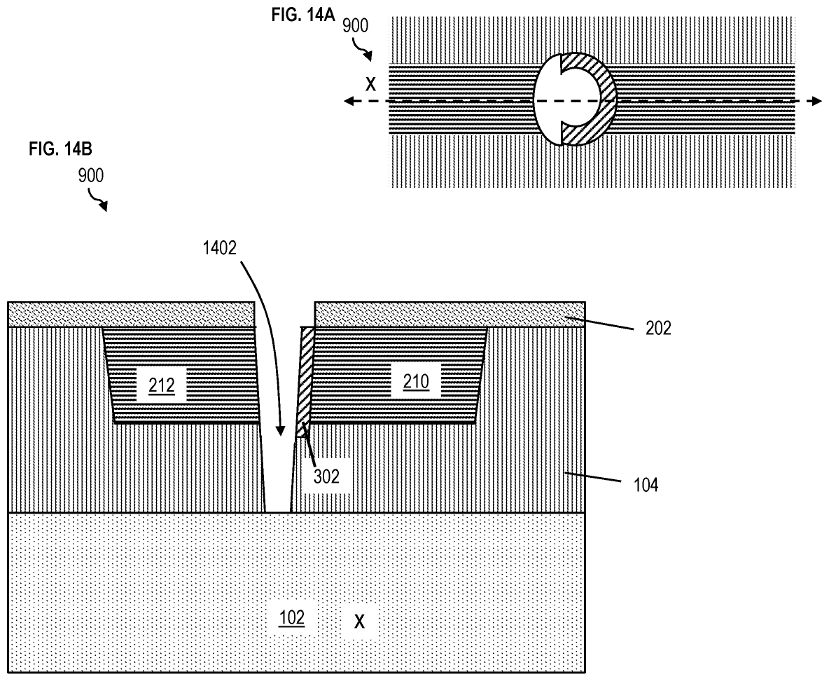

FIGS. 14A and 14B depict the IC 900 after further etching. Etching is performed to expose, for example, contacts (not shown) to one or more devices in the underlayer 102, thereby resulting in a cavity 1402.

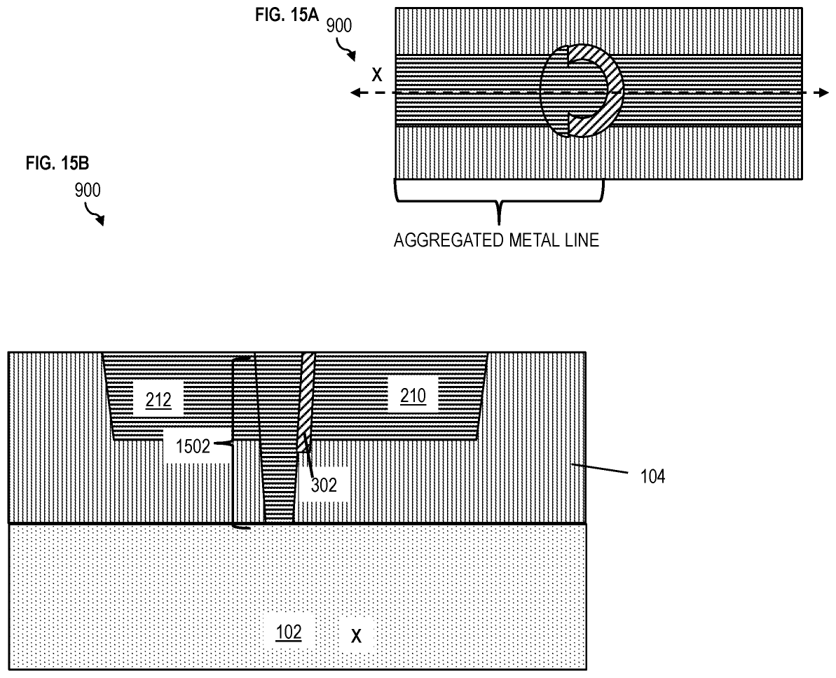

FIGS. 15A and 15B depict the IC 900 after metal fill. Metal is deposited to form conductive via 1502 that fills the empty cavity 1402. The conductive via 1502 abuts both the metal line 212 and the spacer 302. The conductive via 1502 may be referred to as Vx−1. Materials of the deposited metal can include Ru, copper, aluminum, W. Co, gold, etc.

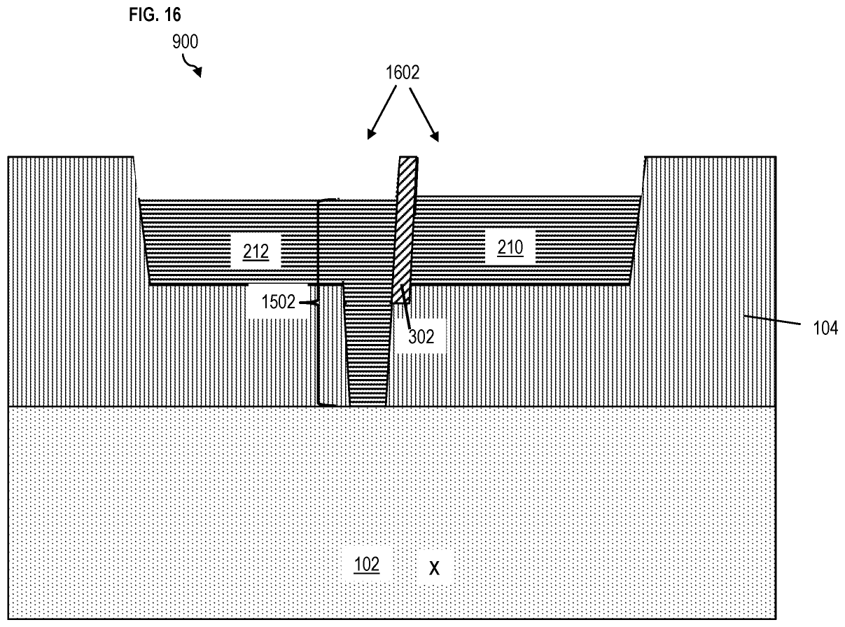

FIG. 16 is a cross-sectional view depicting the IC 900 after conductive via and metal line recess. Etching is performed to selectively recess the metal line 210, the metal line 212, and the conductive via 1502, while the spacer 302 is not etched. The etching results in cavities 1602. A selective wet etch or dry etch may be utilized. The upper portion of the conductive via 1502 can be considered a metal extension to the metal line 212. In FIG. 16, the upper portion of the conductive via 1502 as the metal extension and the metal line 212 can be referred to as an aggregated metal line, which is analogous to aggregated metal line 612.

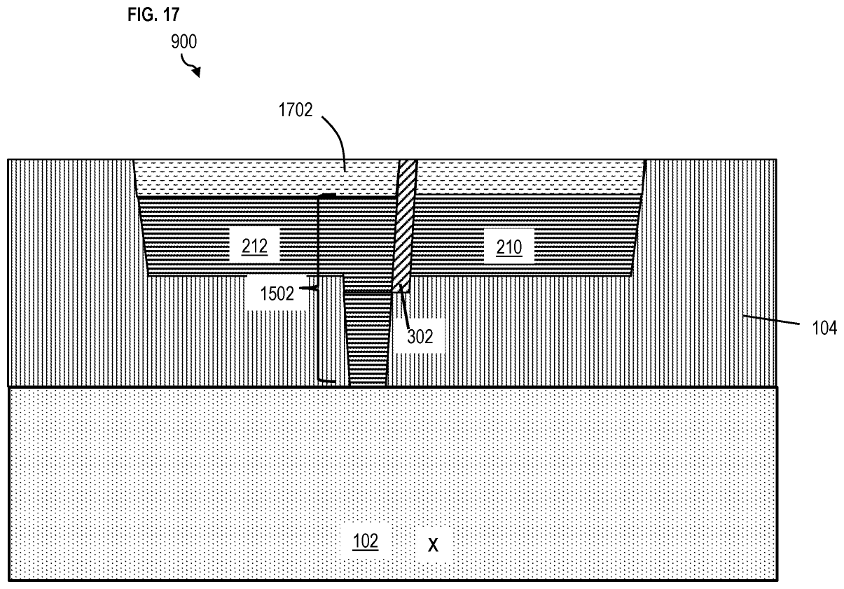

FIG. 17 is a cross-sectional view depicting the IC 900 after dielectric cap formation. Dielectric material is deposited in the cavities 1602 to form a dielectric cap 1702. Chemical mechanical planarization/polishing (CMP) can be performed. The dielectric material of the dielectric cap 1702 can be a different dielectric material than the spacer 302 in order to provide etch selectivity during later fabrication operations. Examples materials of the dielectric cap 1702 can include SiO₂, SiN, SiC, SiOC, SiBCN, SiOCN, AlOx, AlNx, etc.

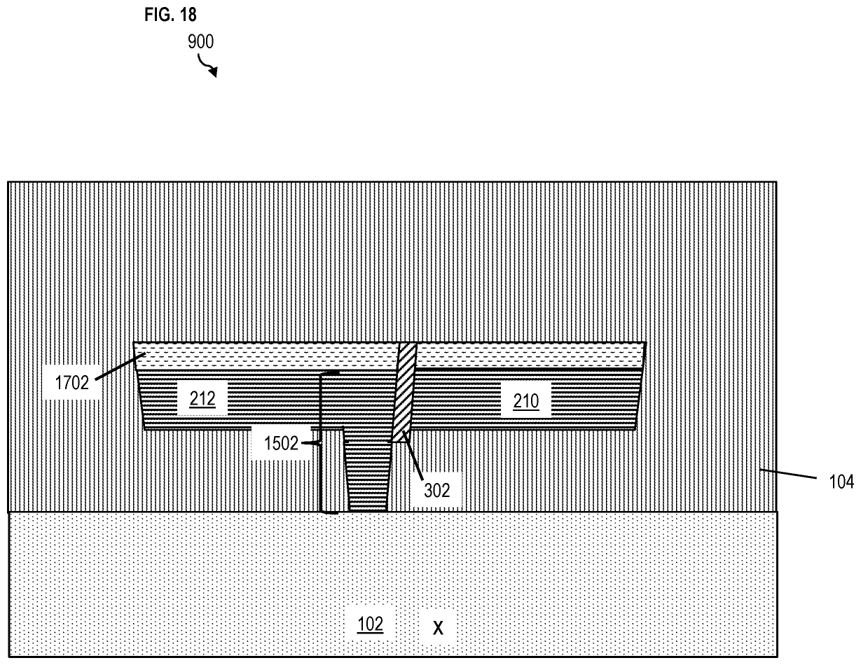

FIG. 18 is a cross-sectional view depicting the IC 900 after ILD fill. Dielectric material is deposited increasing the ILD layer 104 in preparation for further fabrication operations.

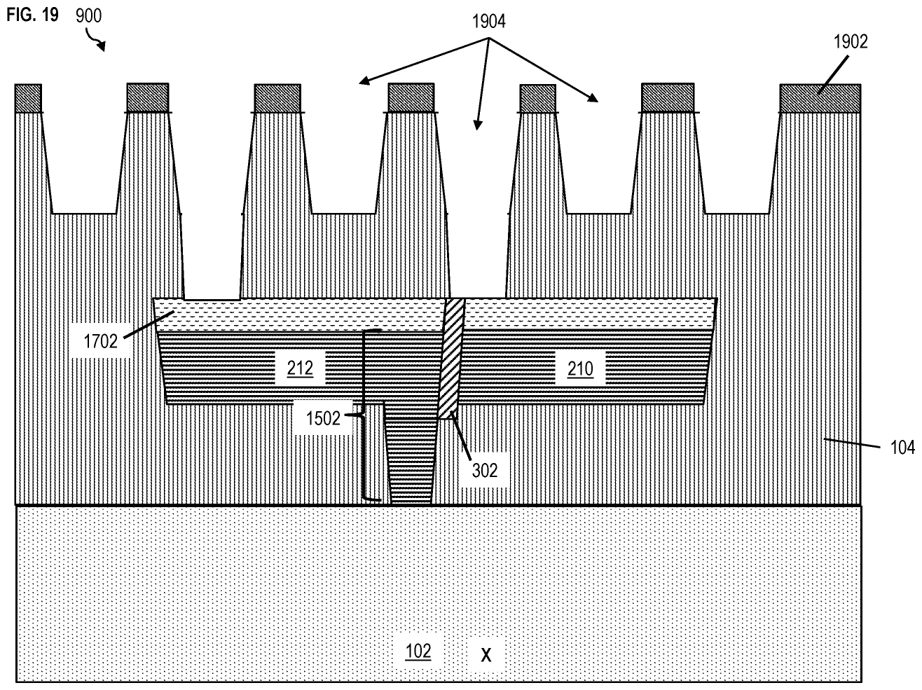

FIG. 19 is a cross-sectional view depicting the IC 900 after metal (Mx+1) patterning and via (Vx) patterning. A hard mask layer 1902 is formed on top of the ILD layer 104. The hard mask layer 1902 is patterned, and the patterned hard mask layer 1902 is utilized to etch through portions of the ILD layer 104, forming cavities 1904. In some cavities 1904 the dielectric cap 1702 is exposed, which is in preparation for further fabrication operations. Also, a top surface of the spacer 302 is exposed in one of the cavities 1904. A wet etch or dry etch may be utilized. Example materials of the hard mask layer 202 can include nitride materials such as silicon nitride, TiN, SiON, etc.

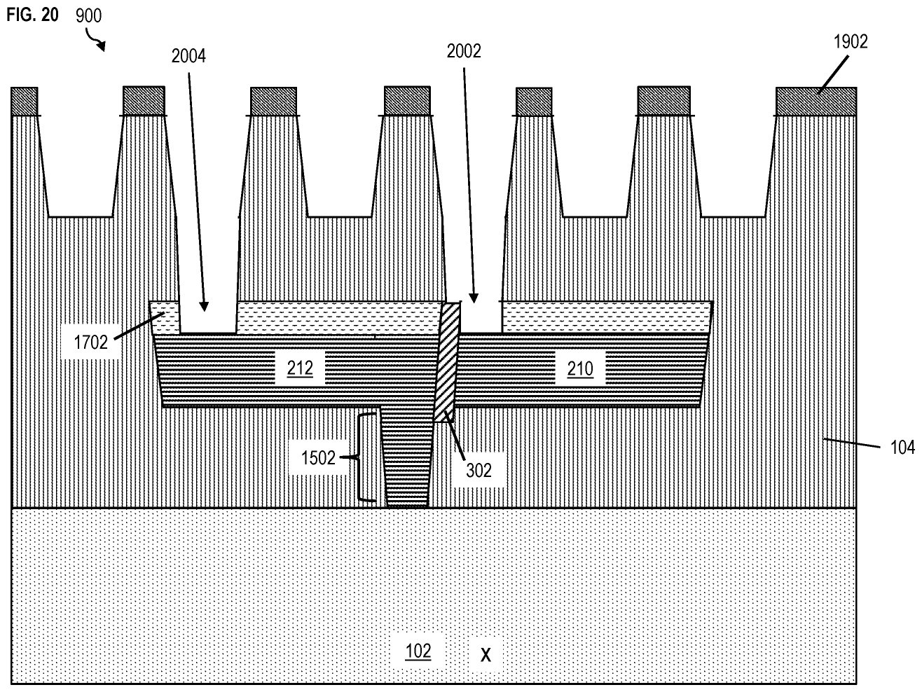

FIG. 20 is a cross-sectional view depicting the IC 900 after selectively opening the dielectric cap. Etching is performed to form openings 2002 and 2004 through the dielectric cap 1702. The opening 2002 exposes a portion of the metal line 210 and a side portion of the spacer 302. The opening 2004 exposes a portion of the metal line 212. The selective etch process does not etch the spacer 302, thereby preventing the via shorting to neighboring metal line 212.

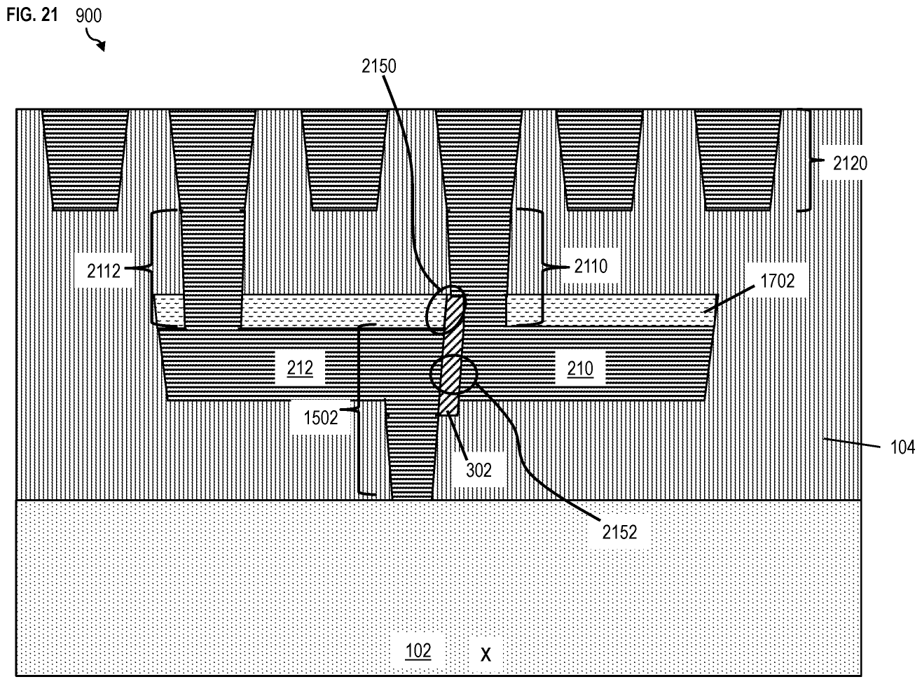

FIG. 21 is a cross-sectional view depicting the IC 900 after metal line (Mx+1) metallization and conductive via (Vx) metallization. Metal is deposited to form conductive via 2110, conductive via 2112, and metal lines 2120. The metal lines 2120 can be referred to as Mx+1 because they are formed above the metal lines 210 and 212 that are referred to as Mx. The conductive vias 2110 and 2112 can be referred to as Vx because they are formed above the conductive via 1502 is referred to as Vx−1. The conductive via 2110 is in contact with both the spacer 302 and metal line 210 below and is in contact with one of the metal lines 2120 above. The conductive via 2112 is in contact with the metal line 212 below and another one of the metal lines 2120 above.

As can be seen in FIG. 21, BEOL scaling has been accomplished to minimize the distance between metal line 212 (e.g., Mx) (including an upper portion of the conductive via 1502) and the conductive via 2110 (e.g., Vx), as depicted by a highlighted circle 2150. As depicted by a highlighted circle 2152, the BEOL scaling minimizes the tip-to-tip distance between the metal line 210 and the metal line 212 including an upper portion of the conductive via 1502.

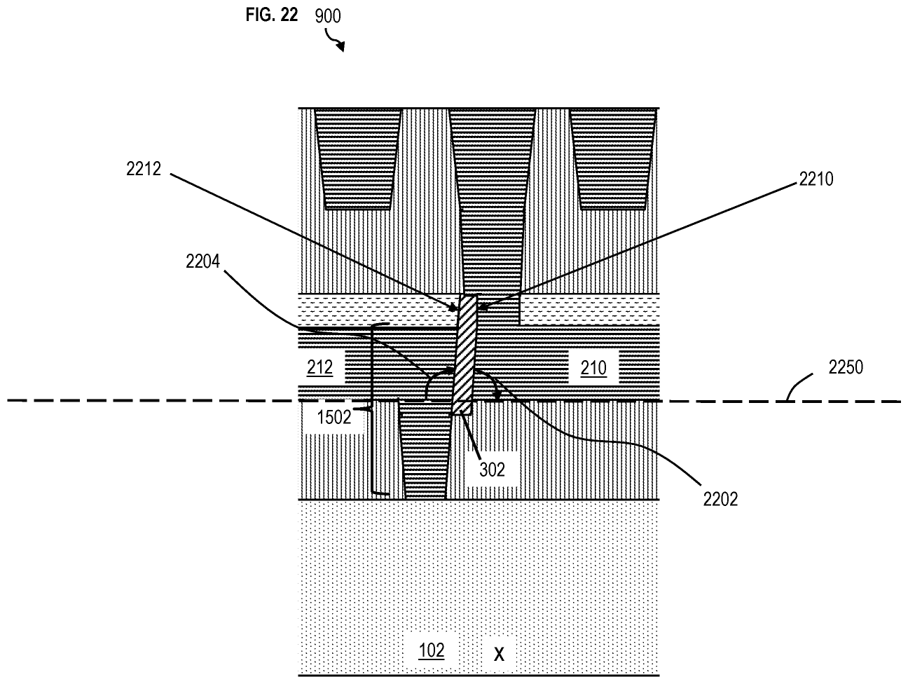

FIG. 22 depicts highlighted portions of the IC 900. An imaginary line 2250 is identified as being coplanar with bottom surfaces of the metal lines 210 and the metal lines 212. In FIG. 22, an angle 2202 is identified between a first side surface 2210 of the spacer 302 and the bottom of the metal line 210 identified by the imaginary line 2250. The angle 2202 is less than 90°. An angle 2204 is identified between a second side surface 2212 of the spacer 302 and the bottom of the metal line 212 identified by the imaginary line 2250. The angle 2204 is greater than 90°. The first side surface 2210 of the spacer 302 is opposite the second side surface 2212.

According to one or more embodiments, a method includes forming a first metal line (e.g., metal line 210) and a second metal line (e.g., metal line 212). The method includes forming a spacer (e.g., spacer 302 and airgap spacer 806) separating the first metal line from the second metal line, the spacer having a flat surface and curved tips 620, where the flat surface abuts the first metal line (e.g., metal line 210) and the curved tips 620 abut the second metal line.

The second metal line includes a metal extension (e.g., metal extension 602 and upper portion of the conductive via 1502), the metal extension being separated from the first metal line by the spacer (e.g., spacer 302 or the airgap spacer 806). The second metal line includes a metal extension, the metal extension (e.g., metal extension 602 and upper portion of the conductive via 1502) having a larger dimension in one direction (e.g., the z-axis) than the second metal line (e.g., metal line 212). The second metal line includes a metal extension (e.g., metal extension 602 and upper portion of the conductive via 1502), the metal extension having a larger dimension in one direction (e.g., the z-axis) than the first metal line (e.g., metal line 210). A top surface of the spacer is coplanar with the first metal line and the second metal line. The flat surface and the curved tips (e.g., curved tips 620) are on opposite sides of the spacer. The spacer has an airgap 802.

According to one or more embodiments, a method includes forming a spacer 302 separating a first metal line (e.g., metal line 210) and a second metal line (e.g., metal line 212). The method includes removing the spacer 302 so as to leave a cavity 702 between the first metal line and the second metal line. The method includes depositing dielectric material to form an airgap spacer 806 in the cavity 702 between the first metal line and the second metal line and to form a dielectric cap 804 above the first and second metal lines.

The airgap spacer 806 includes an airgap 802. The airgap spacer 806 includes a flat surface and curved tips 620, where the flat surface abuts the first metal line and the curved tips 620 abut the second metal line. The second metal line includes a metal extension, the metal extension being separated from the first metal line by the airgap spacer 806. The second metal line includes a metal extension, the metal extension having a larger dimension in one direction than the second metal line. The second metal line includes a metal extension, the metal extension having a larger dimension in one direction than the first metal line.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A structure comprising:
a first metal line and a second metal line; and
a spacer separating the first metal line from the second metal line, the spacer comprising a flat surface and curved tips, wherein the flat surface abuts the first metal line and the curved tips abut the second metal line.

2. The structure of claim 1, wherein the second metal line includes a metal extension, the metal extension being separated from the first metal line by the spacer.

3. The structure of claim 1, wherein the second metal line includes a metal extension, the metal extension having a larger dimension in one direction than the second metal line.

4. The structure of claim 1, wherein the second metal line includes a metal extension, the metal extension having a larger dimension in one direction than the first metal line.

5. The structure of claim 1, wherein a top surface of the spacer is coplanar with the first metal line and the second metal line.

6. The structure of claim 1, wherein the flat surface and the curved tips are on opposite sides of the spacer.

7. The structure of claim 1, wherein the spacer comprises an airgap.

8. A method comprising:
forming a first metal line and a second metal line; and
forming a spacer separating the first metal line from the second metal line, the spacer comprising a flat surface and curved tips, wherein the flat surface abuts the first metal line and the curved tips abut the second metal line.

9. The method of claim 8, wherein the second metal line includes a metal extension, the metal extension being separated from the first metal line by the spacer.

10. The method of claim 8, wherein the second metal line includes a metal extension, the metal extension having a larger dimension in one direction than the second metal line.

11. The method of claim 8, wherein the second metal line includes a metal extension, the metal extension having a larger dimension in one direction than the first metal line.

12. The method of claim 8, wherein a top surface of the spacer is coplanar with the first metal line and the second metal line.

13. The method of claim 8, wherein the flat surface and the curved tips are on opposite sides of the spacer.

14. The method of claim 8, wherein the spacer comprises an airgap.

15. A method comprising:
forming a spacer separating a first metal line and a second metal line;
removing the spacer so as to leave a cavity between the first metal line and the second metal line; and
depositing dielectric material to form an airgap spacer in the cavity between the first metal line and the second metal line and to form a dielectric cap above the first and second metal lines.

16. The method of claim 15, wherein the airgap spacer comprises an airgap.

17. The method of claim 15, wherein the airgap spacer comprises a flat surface and curved tips, the flat surface abutting the first metal line and the curved tips abutting the second metal line.

18. The method of claim 15, wherein the second metal line includes a metal extension, the metal extension being separated from the first metal line by the airgap spacer.

19. The method of claim 15, wherein the second metal line includes a metal extension, the metal extension having a larger dimension in one direction than the second metal line.

20. The method of claim 15, wherein the second metal line includes a metal extension, the metal extension having a larger dimension in one direction than the first metal line.
